(19) United States
(12) Patent Application Publication
(10) Pub. No.: US 2014/0285970 A1
(43) Pub. Date: Sep. 25, 2014

(54) Electric Power Conversion System

(71) Applicant: Hitachi Automotive Systems, Ltd., Hitachinaka-shi, Ibaraki (JP)

(72) Inventors: Hidenori Shinohara, Hitachinaka (JP); Akihiro Goto, Yokohama (JP); Tadahiko Chida, Tokyo (JP)

(21) Appl. No.: 14/353,698

(22) PCT Filed: Oct. 11, 2012
(86) PCT No.: PCT/JP2012/076289

§ 371 Date: Apr. 23, 2014

(30) Foreign Application Priority Data
Oct. 28, 2011 (JP) 2011-237978

(51) Int. Cl. H05K 7/20; H05K 1/02

(52) U.S. Cl. CPC H05K 7/2089; H05K 1/0272
USPC 361/689

(57) ABSTRACT

There is provided an electric power conversion system. Bus bars 160 and 161 as heat-producing elements are provided on a circuit board assembly 150, and the circuit board assembly 150 is fixed to a DC-DC converter case 110. The DC-DC converter case 110 is integrated with an inverter 200, and a refrigerant channel 101 is formed therebetween. By bringing newly provided bus bar solder-fixed parts 160c, 160d, 161c, and 161d of those bus bars into contact with a refrigerant channel range 101A, heat generated at the bus bars 160 and 161 is released into a refrigerant via a metal board and the DC-DC converter case 110, respectively.

### TECHNICAL FIELD

The invention relates to an electric power conversion system, and in particular, to an electric power conversion system for integrating a DC-DC converter with an inverter.

### BACKGROUND ART

An inverter for driving a motor by use of a high-voltage battery for power driving is mounted in an electric vehicle, and a plug-in hybrid car, respectively. Further, besides the high-voltage battery, a low-voltage battery for actuating auxiliaries such as vehicle lights and a radio are mounted therein. A DC-DC converter for use in electric power conversion either from the high-voltage battery to the low-voltage battery, or from the low-voltage battery to the high-voltage battery is mounted in these vehicles (refer to, for example, Patent Literature

In the case of those vehicles, it is desirable to raise a ratio of a cabin to a volume of the vehicle in whole as much as possible, thereby enhancing comfort in the cabin. For this reason, it is desired that the inverter and the DC-DC converter are mounted outside the cabin, in a space as small as possible, inside an engine room, in particular.

### CITATION LIST

### Patent Literature

Patent Literature 1: Japanese Patent No. 4300717

### SUMMARY OF INVENTION

### Technical Problem

Now, a temperature environment inside the engine room is higher than that in the conventional usage environment, and usage in a high temperature range, in particular, is presumed to hasten not only deterioration in the respective control functions of the inverter, and the DC-DC converter, but also degradation of structural parts. For this reason, as a cooling mechanism for devices such as the inverter, and the DC-DC converter, these devices are cooled by use of a refrigerant generally made up of water and a mixture, and higher cooling efficiency of the cooling mechanism including this cooling method, together with improvement in space-saving characteristic, has become an important technical factor.

However, electronic components mounted in the inverter, and the DC-DC converter, respectively, are high in heat value, requiring a complex cooling method, such as addition of components for use in cooling the electronic components, provision of a fan, etc., thereby causing a problem in that a space for onboard units will increase.

It is therefore an object of the invention to provide an electric power conversion system capable of enhancing cooling efficiency.

### Solution to Problem

(1) In order to achieve the object of the invention, the invention provides an electric power conversion system incorporating a DC-DC converter, and an inverter integrally fixed to the DC-DC converter, the electric power conversion system including a refrigerant channel formed between the DC-DC converter and the inverter. The DC-DC converter is provided with a circuit board made of a metal, and a bus bar soldered to the circuit board through the intermediary of solder-fixed parts, the solder-fixed parts of the bus bar include the solder-fixed part electrically uncoupled, in addition to the solder-fixed part at two spots, serving as electrically necessary coupling in terms of a circuit, and the solder-fixed part electrically uncoupled is disposed in the vicinity of a range opposed to the refrigerant channel. With the adoption of such a configuration described as above, cooling efficiency of the electric power conversion system may be enhanced.

(2) Under (1) as above, a gravity center of the solder-fixed part of the bus bar is preferably disposed inside a triangle formed by linking three points of the (solder-) fixed part of the bus-bar with each other.

(3) Under (1) as above, a thermally-conductive grease or a heat dissipation sheet, disposed between the circuit board made of the metal and a case of the DC-DC converter, fixed thereto, is preferably provided.

### Advantageous Effects of Invention

According to the present invention, the cooling efficiency of the electric power conversion system may be enhanced.

### BRIEF DESCRIPTION OF DRAWINGS

FIG. 1 is an assembly view showing a configuration as a whole of an electric power conversion system according to one embodiment of the invention;

FIG. 2 is a perspective view of a partial section of an inverter used in the electric power conversion system according to the one embodiment of the invention, showing a configuration thereof;

FIG. 3 is a perspective view of the DC-DC converter used in the electric power conversion system according to the one embodiment of the invention, in which (A) is a top surface view and (B) is a bottom face view;

FIG. 4 is a perspective view showing an internal configuration of the DC-DC converter used in the electric power conversion system according to the one embodiment of the invention;

FIG. 5 is a perspective view showing a configuration of a bus bar used in a circuit board assembly of the DC-DC converter of the electric power conversion system according to the one embodiment of the invention;

FIG. 6 is a perspective view showing a configuration of a bus bar used in the circuit board assembly of the DC-DC converter of the electric power conversion system according to the one embodiment of the invention;

FIG. 7 is a plan view showing the position of a gravity center of the bus bar used in the circuit board assembly of the DC-DC converter of the electric power conversion system according to the one embodiment of the invention;

FIG. 8 is a schematic representation of a cooling structure of the bus bar used in the circuit board assembly of the DC-DC converter of the electric power conversion system according to the one embodiment of the invention;

FIG. 9 is a schematic representation of the cooling structure of the bus bar used in the circuit board assembly of the DC-DC converter of the electric power conversion system according to the one embodiment of the invention; and

FIG. 10 is a plan view showing a configuration of the circuit board assembly of the DC-DC converter of the electric power conversion system according to the one embodiment of the invention.

### DESCRIPTION OF EMBODIMENTS

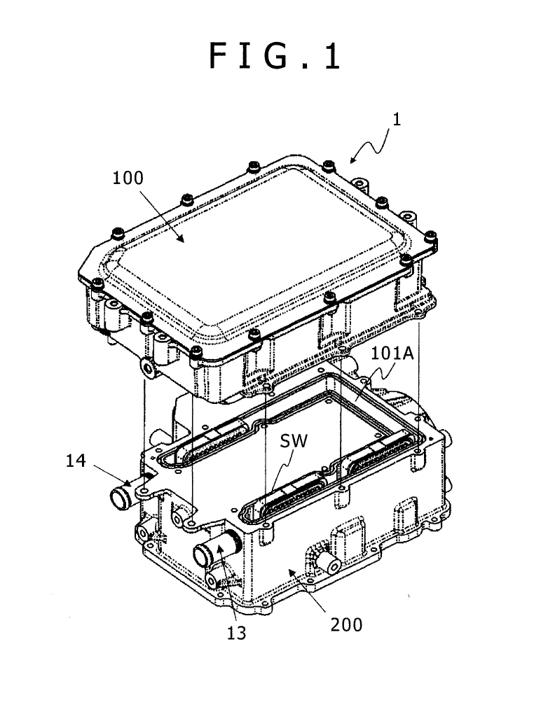

A configuration of an electric power conversion system according to one embodiment of the invention is described below with reference to FIGS. 1 through 10.

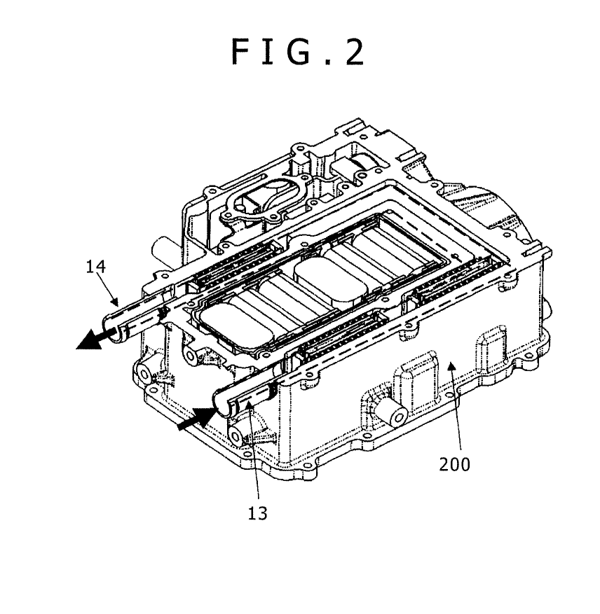

First, a configuration as a whole of the electric power conversion system according to the present embodiment of the invention is described with reference to FIGS. 1, and 2.

FIG. 1 is an assembly view showing the configuration of the electric power conversion system according to the one embodiment of the invention, as a whole. FIG. 2 is a perspective view of a partial section of an inverter used in the electric power conversion system according to the one embodiment of the invention, showing a configuration of the inverter.

The electric power conversion system 1 is made up of a DC-DC converter 100 and an inverter 200 integrated therewith as shown in FIG. 1. The DC-DC converter 100 and the inverter 200 in such a state as separated from each other are shown in FIG. 1. The DC-DC converter 100 is fixed on the underside of a case of the inverter 200 with bolts.

The electric power conversion system 1 is applied to the electric vehicle, etc. and the inverter 200 drives a motor for driving by use of an electric power from an on-board high-voltage battery. A low-voltage battery for actuating auxiliaries such as vehicle lights and a radio is mounted in a vehicle, and the DC-DC converter 100 executes electric power conversion either from the high-voltage battery to the low-voltage battery or from the low-voltage battery to the high-voltage battery.

As shown in FIGS. 1 and 2, the inverter 200 includes an inlet piping 13 and an outlet piping 14. The inlet piping 13 and the outlet piping 14 are each connected to a refrigerant channel 101A formed in the inverter 200. The refrigerant channel 101A of the inverter 200 has an opening formed in the top thereof. The opening is covered upon the DC-DC converter 100 being fixed to the inverter 200. By so doing, the refrigerant channel through which a refrigerant flows is formed between the inverter 200 and the DC-DC converter 100. A module SW of a semiconductor switching element (IGBT, etc.) protrudes inside the refrigerant channel 101A, as shown in the figures, so that the semiconductor switching element is immersed in the refrigerant flowing through the refrigerant channel 101A. The refrigerant flows through the inlet piping 13 into the channel, flowing out through the outlet piping 14.

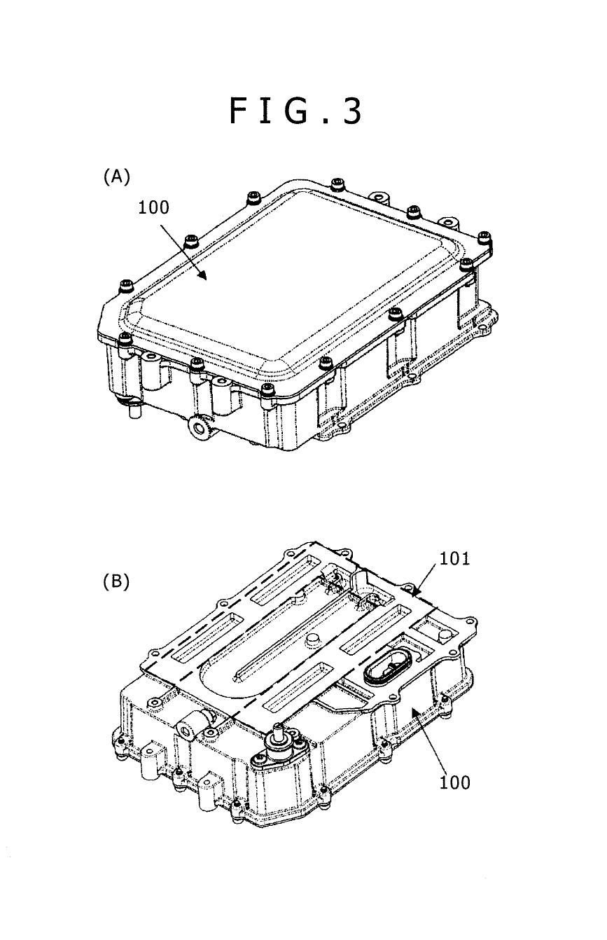

Next, a configuration of the DC-DC converter used in the electric power conversion system according to the present embodiment is described below with reference to FIG. 3. FIGS. 3(A) and 3(B) each are a perspective view of the DC-DC converter used in the electric power conversion system according to the one embodiment of the invention. FIG. 3(A) is a top surface view, and FIG. 3(B) is a bottom face view.

A refrigerant channel range 101 is shown on the bottom face of the DC-DC converter 100. The refrigerant channel range 101 is a range that is opposed to the refrigerant channel 101A shown in FIG. 2. Heat generated by the DC-DC converter 100 is released in the refrigerant channel range 101.

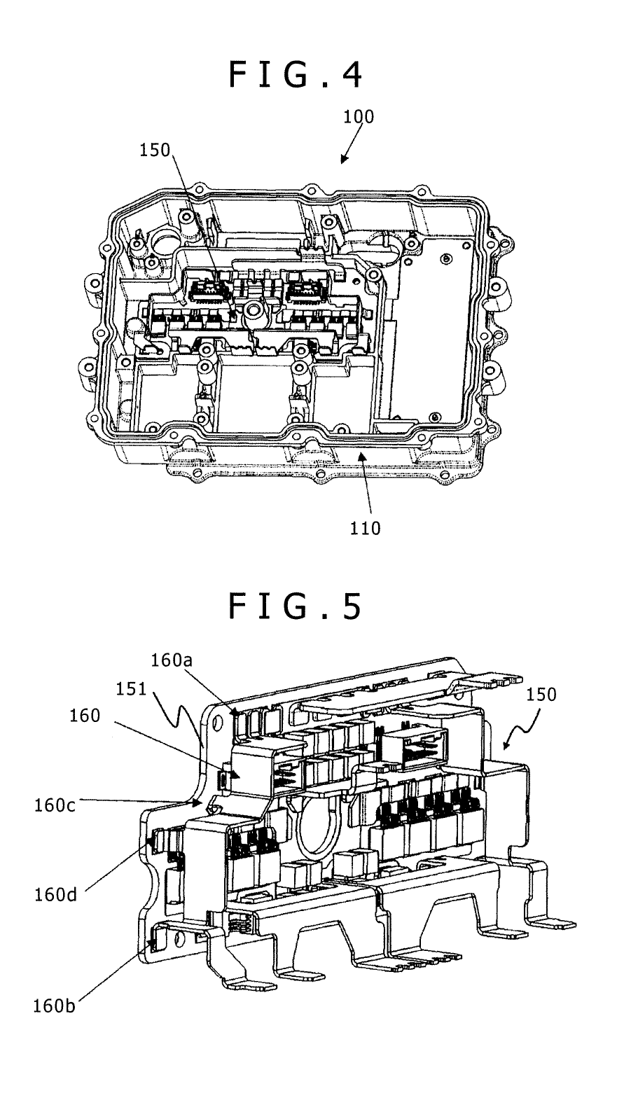

Then, an internal configuration of the DC-DC converter used in the electric power conversion system according to the present embodiment is described below with reference to FIG. 4.

FIG. 4 is a perspective view showing the internal configuration of the DC-DC converter used in the electric power conversion system according to the one embodiment of the invention. FIG. 4 shows the DC-DC converter shown in FIG. 3(A), with a top cover thereof, in as-removed state.

A circuit board assembly 150 is fixed to the interior of the DC-DC converter 100. The bottom face of the circuit board of the circuit board assembly 150 is in face contact with the plane of a DC-DC converter case 110. The DC-DC converter case 110 is made by die casting of aluminum. The circuit board assembly 150 is provided with bus bars through which a high electric current flows, and a configuration as well as a heat dissipation structure thereof are described with reference to FIG. 5 and subsequent figures.

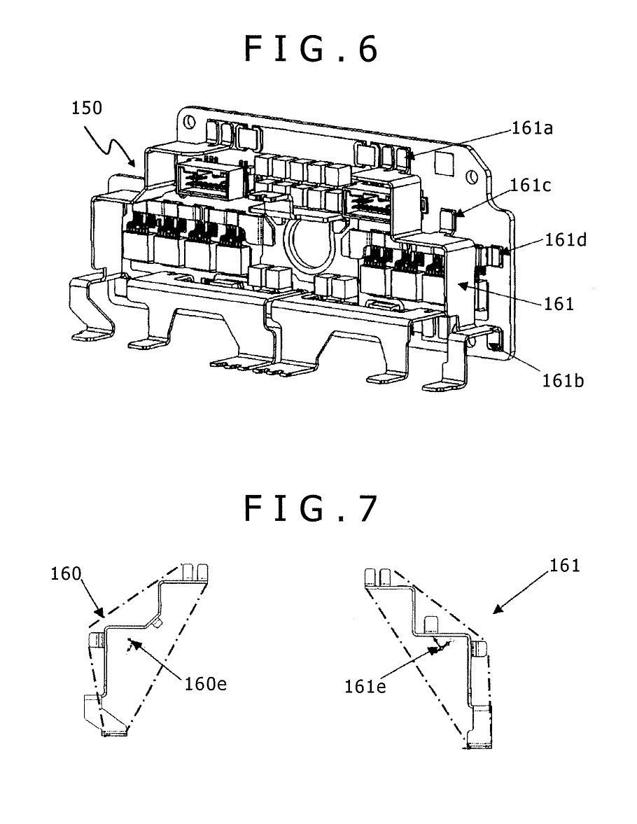

Next, a configuration of the bus bars for use in the circuit board assembly 150 of the DC-DC converter of the electric power conversion system according to the present embodiment is described below with reference to FIGS. 5 and 6.

FIGS. 5 and 6 each are a perspective view showing the configuration of the bus bar for use in the circuit board assembly 150 of the DC-DC converter of the electric power conversion system according to the one embodiment of the invention.

FIG. 5 is the perspective view of the bus bar, as seen from the left-hand side direction, and FIG. 6 is the perspective view of the bus bar, as seen from the right-hand side direction.

The circuit board assembly 150 disposed in the DC-DC converter is provided with the bus bars 160, 161. The bus bars 160, 161 each are formed in such a shape as bent in stages, in a crank-like manner, to be fixed to a metal board 151. At this point in time, flat parts of the bus bars 160, 161, respectively, are fixed to the metal board 151 in such a way as to be orthogonal to the plane part of the metal board 151. Accordingly, a ratio of an area occupied by each of the bus bars 160, 161 to that of the plane part of the metal board 151 can be reduced, so that packaging efficiency is enhanced.

With the metal board 151, an interconnection layer is formed on a board made of aluminum, etc. through the intermediary of an insulating layer. The bus bars 160, 161 each are connected to the interconnection layer to be fixed thereto. The bus bars 160, 161 each are made of copper, being a conductor band-like in shape, as shown in the figures. The bus bars 160, 161 each are, for example, ten and several mm in width, and 1 mm in thickness. Further, since the bus bars 160, 161 each are made of copper, and are large in cross-sectional area, the electrical resistance thereof is small. However, because a high electric-current in a range of, for example, 100 A to 200 A will flow to the bus bar on a low voltage side, the bus bar will have a large heat value.

The bus bar 160 is fixed to the metal board 151 with the use of a solder. At the time of fixing with the use of the solder, the fixing is implemented by a solder-reflow process. The bus bar 160 is provided with bus bar solder-fixed parts 160a, 160b, 160c, 160d, located at four spots, respectively. The bus bar solder-fixed parts 160a, 160b, located at the two spots among the four spots, respectively, are electrically coupled to the interconnection layer of the metal board 151, in terms of an electric circuit, serving as necessary coupling in terms of a circuit.

In contrast, the bus bar solder-fixed parts 160c, 160d each are a coupling portion of the bus bar, newly provided in order to release the heat in the refrigerant channel range 101 via the metal board 151, and the DC-DC converter case 110, respectively.

The bus bar 161 is similarly fixed to the metal board 151 with the use of the solder. The bus bar 161 is provided with bus bar solder-fixed parts 161a, 161b, 161c, and 161d, located at four spots, respectively. The bus bar solder-fixed parts 161a, 161b, located at the two spots among the four spots, respectively, are coupled to the interconnection layer of the metal board 151, in terms of a circuit, representing a coupling necessary, in terms of the circuit. In contrast, the bus bar solder-fixed parts 161c, 161d each are a coupling portion that is newly provided in order to release the heat in the refrigerant channel range 101 via the metal board 151, and the DC-DC converter case 110, respectively.

Next, the position of a gravity center of the bus bar used in the circuit board assembly 150 of the DC-DC converter of the electric power conversion system according to the present embodiment is described below with reference to FIG. 7.

FIG. 7 is a plan view showing the position of a gravity center of the bus bar used in the circuit board assembly of the DC-DC converter of the electric power conversion system according to the one embodiment of the invention. In the figure, reference signs identical to those in FIGS. 5 and 6 indicate parts identical thereto, respectively.

FIG. 7 shows the bus bar 160 and the bus bar 161.

In order to cause the bus bars 160, 161 to stand alone when the bus bars 160, 161 each are mounted on the metal board 151, respective gravity centers 160e, 161e with respect to respective single components of the bus bars 160, 161, are positioned inside a solder-fixed part three-point frame, respectively. Herein, in the case of FIG. 7(A), the solder-fixed part of the bus bar 160 is present at four spots. Accordingly, a triangle indicated by a broken line in the figure, the triangle being formed by linking the three sots among the four spots, with each other, such that an area thereof is rendered the largest, is taken as the solder-fixed part three-point frame.

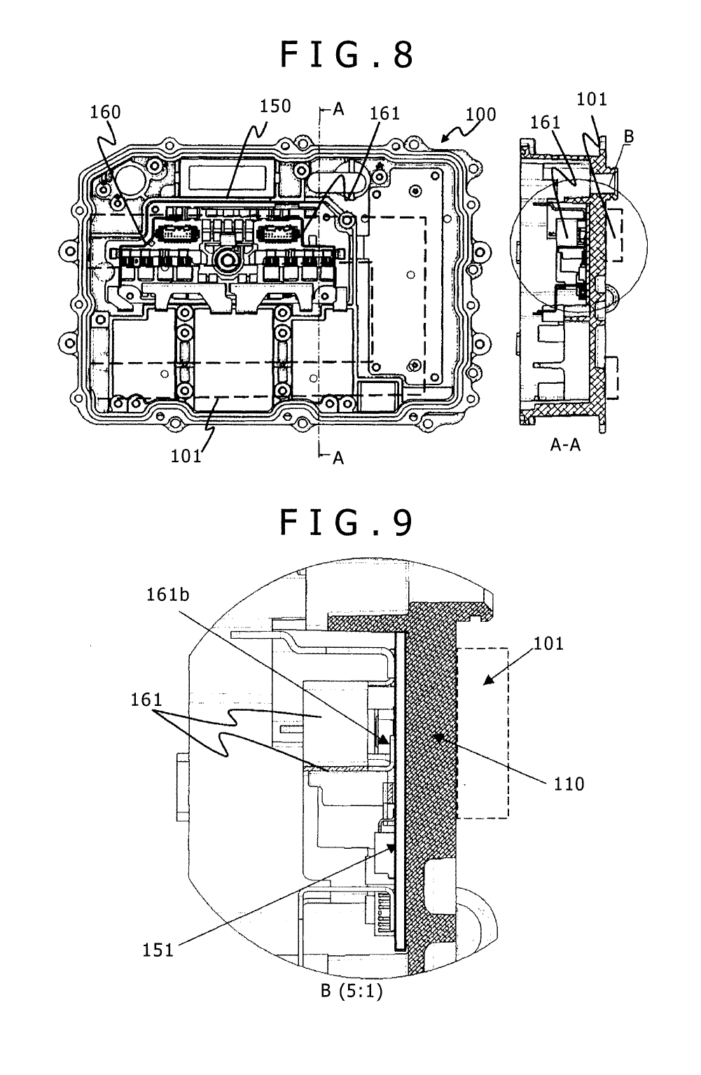

Next, a cooling structure of the bus bar used in the circuit board assembly of the DC-DC converter of the electric power conversion system according to the present embodiment is described below with reference to FIGS. 8 and 9.

FIGS. 8 and 9 each are a schematic representation of the cooling structure of the bus bar used in the circuit board assembly of the DC-DC converter of the electric power conversion system according to the one embodiment of the invention. In the figures, reference signs identical to those in FIGS. 1 through 7, respectively, indicate parts identical thereto, respectively. FIG. 8 is a plan view of the DC-DC converter with a top cover thereof, in as-removed state, and a sectional arrow view taken on line A-A. FIG. 9 is an enlarged sectional view of a circled part in FIG. 8.

With the circuit board assembly 150, the board thereof is screwed to the DC-DC converter case 110. The bus bars 160, 161 are soldered to the metal board 151. At this point in time, the bus bars 160, 161, and grounded parts of the metal board 151 (the solder-fixed parts 160a through 161d in FIGS. 5 and 6) are in contact with the refrigerant channel range 101 via the metal board 151, and the DC-DC converter case 110, respectively.

Further, when the metal board 151 is fixed to the DC-DC converter case 110, a thermally-conductive grease is applied therebetween in order to enhance heat-release characteristics. Metals are in face-contact with each other between the metal board 151 and the DC-DC converter case 110, however, this is a point-contact as microscopically seen. Therefore, the thermally-conductive grease is interposed there between in order to improve contact performance to thereby secure thermal conductivity. However, since the thermal conductivity of the thermally-conductive grease is poorer than that of metal, the thermally-conductive grease is preferably as small as possible in thickness. In this respect, the thickness of the thermally-conductive grease can be reduced by increasing a tighten-up amount of a screw for use in fixing the circuit board assembly 150 to the DC-DC converter case 110. Further, a heat dissipation sheet can be used in place of the thermally-conductive grease.

As previously described, the newly provided bus bar solder-fixed parts 160c, 160d, 161c, and 161d are disposed in the refrigerant channel range 101, or in the vicinity thereof. Since the bus bar solder-fixed parts 160c, 160d, 161c, 161d each are positively brought into contact with the refrigerant channel range 101, as described above, the heat-release characteristics can be dramatically enhanced.

As a result of addition of the bus bar solder-fixed parts 160c, 160d, 161c, 161d, and the bus bars 160, 161 each can stand alone when the bus bars 160, 161 each are disposed on the metal board 151 upon assembling, so that safety is increased, and work efficiency at the time of assembling as well as a solder-reflow work.

Still further, a high anti-shock characteristic is generally required of the electric power conversion system mounted in a vehicle in order to cope with vibration occurring at the time of travelling, however, if the bus bar solder-fixed parts 160c, 160d, 161c, 161d are additionally provided, as described above, stress applied to the bus bar solder-fixed parts 160a, 160b, necessary in terms of the circuit, when vibration is added to the bus bars, can be relaxed, so that coupling reliability of the bus bar solder-fixed parts 160a, 160b will be enhanced. Accordingly, the electric power conversion system high in anti-shock characteristic can be implemented.

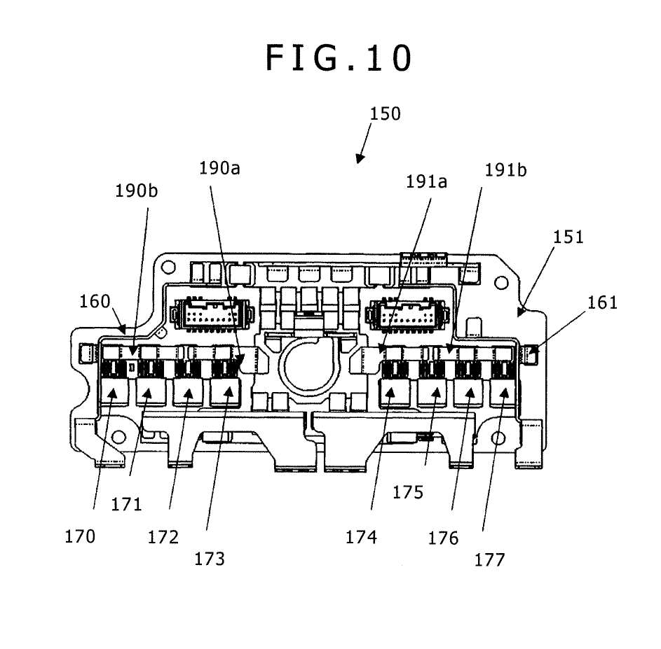

Next, a configuration of the circuit board assembly of the DC-DC converter of the electric power conversion system according to the present embodiment is described below with reference to FIG. 10.

FIG. 10 is a plan view showing the configuration of the circuit board assembly of the DC-DC converter of the electric power conversion system according to the one embodiment of the invention. Further, in the figure, reference signs identical to those in FIGS. 1 through 9, respectively, indicate parts identical thereto, respectively.

Herein, there are described semiconductor packages 170 through 177 as well as bus bars 190a, 190b, and 191a, 191b, mounted in the circuit board assembly 150.

Now, the semiconductor packages 170, 171, 172, 173 are electrically coupled with each other via the bus bars 190a, 190b, respectively. If these bus bars each are formed in the shape of a flat plate in parallel with the circuit board assembly 150, and are structured such that a height thereof, from the circuit board, is low, as shown in FIG. 10, this will cause an eddy current in a reverse direction to occur to the circuit board assembly 150 when an electric current flows through the bus bars, so that a magnetic field in the vicinity of the bus bar will become smaller, and inductance of these bus bars can be reduced. The lower the height of the bus bar is, the greater this effect will be.

If these bus bars are rendered lower in inductance, this will enable a surge voltage applied to the semiconductor package to be checked, thereby enabling a lower-voltage semiconductor package to be used. In general, since a low-voltage semiconductor package is low in on-resistance, loss is small. Accordingly, use of this bus bar enables the loss of the semiconductor package to be reduced, thereby reducing the heat value of the circuit board assembly 150. As a result, it is possible to enhance efficiency of the electric power conversion system using this circuit board. Further, an example in which the bus bar 190a is separated from the bus bar 190b is described as above; however, even if these bus bars are integrated with each other, the same effect can be obtained. Still further, the semiconductor packages 170 through 173 and the bus bars 190a, 190b are described above; however, the same can be said with reference to the semiconductor packages 174 through 177 and the bus bars 191a, 191b.

While the preferred embodiment of the invention has been described using specific terms, such description is for illustrative purposes only, and it is therefore to be understood that, in interpretation of the present invention, a corresponding relationship between the description of the preferred embodiment and the description of following claims be not limited and restricted in any way by the description given as above. For example, in the case of the preferred embodiment described as above, the electric power conversion system mounted in a vehicle such as PHEV or EV, etc. is described by way of example; however, the application of the invention is not limited thereto, and the invention is also applicable to the electric power conversion system for use in a vehicle for a construction machine, etc.

As described above, with the present embodiment, it is possible to provide an electric power conversion system capable of preventing deterioration in the function of the system, and progress in component degradation, due to a high-temperature environment, and checking an increase in system size.

Further, an increase in the number of parts for cooling purposes is checked to thereby enable a manufacturing cost to be educed.

Still further, safety at the time of assembling parts can be established to thereby enhance assembling performance.

### LIST OF REFERENCE SIGNS

13 . . . Refrigerant inlet piping

14 . . . Refrigerant outlet piping

100 . . . DC-DC converter

101 . . . Refrigerant channel range

110 . . . DC-DC converter case

150 . . . Circuit board assembly

151 . . . Metal board

160, 161, 190a, 190b, 191a, 191b . . . Bus bar

160a, 160b, 161a, 161b . . . Bus bar solder-fixed part

160c, 160d, 161c, 161d . . . Bus bar solder-fixed part

160e, 161e . . . Bus bar gravity center

170 through 177 . . . Semiconductor package

200 . . . Inverter

1. An electric power conversion system incorporating a DC-DC converter, and an inverter integrally fixed to the DC-DC converter, the electric power conversion system comprising:
a refrigerant channel formed between the DC-DC converter and the inverter,
wherein the DC-DC converter includes:
a circuit board made of a metal; and
a bus bar soldered to the circuit board through the intermediary of solder-fixed parts,
wherein the solder-fixed parts of the bus bar include the solder-fixed part electrically uncoupled, in addition to the solder-fixed part at two spots, serving as electrically necessary coupling in terms of a circuit, and
wherein the solder-fixed part electrically uncoupled is disposed in the vicinity of a range opposed to the refrigerant channel.

2. The electric power conversion system according to claim 1,
wherein a gravity center of the fixed part of the bus bar is disposed inside a triangle formed by linking three points of the solder-fixed part of the bus bar with each other.

3. The electric power conversion system according to claim 1, further comprising:
a thermally-conductive grease or a heat dissipation sheet, disposed between the circuit board made of the metal and the a case of the DC-DC converter, fixed thereto.
